(19) United States
(12) Patent Application Publication
(10) Pub. No.: US 2008/0224171 A1
(43) Pub. Date: Sep. 18, 2008

(54) Light Emitting Device with Filtering Layer

(75) Inventor: Philippe Ballet, Lans-En-Vercors (FR)

Correspondence Address: OBLON, SPIVAK, MCCLELLAND MAIER & NEUSTADT, P.C., 1940 DUKE STREET, ALEXANDRIA, VA, 22314, US

(73) Assignee: Commissariat A L'Energie Atomique, Paris (FR)

(21) Appl. No.: 12/064,914

(22) PCT Filed: Aug. 31, 2006
(86) PCT No.: PCT/EP06/65886

§ 371 Date: Feb. 26, 2008

(30) Foreign Application Priority Data
Sep. 5, 2005 (FR) 05 52680

(51) Int. Cl. H01L 33/00

(52) U.S. Cl. 257/103; 257/E33.013

(57) ABSTRACT

A light emitting device including, between an input mirror and an output mirror forming a cavity, the output mirror having a reflectivity strip, a stack itself including an etch stop layer and an active layer. The stop layer is adapted to filter at least wavelengths lower than the lower limit of the reflectivity strip.

### TECHNICAL FIELD AND PRIOR ART

The invention concerns the field of light emitting devices such as those disclosed for example in the document FR-2 833 757.

This document describes a process for manufacturing a light emitting device in which a stop layer is inserted in the structure.

FIG. 1 represents such a stack described in this prior document, which comprises, between two Bragg mirrors 2, 4, barrier layers 6, 8, a well layer 10 and a stop layer 12.

The stop layer 12 is in CdHgTe, with an alloy composition equal to that of the photon emitter well 10. The advantage of such a device is that the stop layer 12 no longer induces optical loss and can even participate in the emission of light. In practice, the participation of this layer in the emission of light is not optimal since the maximum of the electrical field, in other words the point of maximum coupling between the photons and the microcavity, is situated at the level of the well layer 10.

This microcavity of FIG. 1 produces a non monochromatic radiation but of low spectral width due coupling with the microcavity. This radiation is for example used to analyse the presence of certain gases. To do this, the composition of the well layer is chosen to obtain an optimal spectral overlap between the emitted radiation and the absorption spectrum of the gas considered.

Microcavities of this type have a defect, which is to offer a non guaranteed spectral selectivity. The spectral width of the photoluminescence spectrum is too high to allow a complete selectivity via coupling to the microcavity.

FIG. 2 shows a photoluminescence spectrum (curve I) typical of these known structures. This spectrum has a tail 20, on the high energies side, which is intrinsic to the emission of CdHgTe at ambient temperature. Superimposed on this spectrum is also represented a curve II, or transmission spectrum typical of a pair of Bragg mirrors (Fabry-Perrot resonator) such as those that are added to the stack CdHgTe to form the final emitting device. The reflectivity strip of the mirrors (% T=0) has a finite width and shows, at the resonance wavelength λᵣ, a transmission peak 22. The finite width of the reflectivity strip means that this does not cover the high energy tail 20 of the photoluminescence spectrum.

The final emission of the emitting device is the result of the filtering by the mirrors of the optical emission (photoluminescence). This can be seen in FIG. 3. The refinement of the principal emission ray 24 can clearly be seen (principal advantage of the microcavity) but it can also be seen that the cavity allows stray radiation 26 to pass through on the high energies side.

The presence of this stray radiation 26 drastically reduces the spectral selectivity of such a device. Indeed, even if the stray intensity is considerably less than that of the principal peak, the first may however (which is frequently the case) spectrally coincide with the absorption rays of a compound present in much higher proportion than the gas to be analysed. This may be a particular hindrance if the stray emission corresponds to the absorption domain of water molecules.

The emission spectrum of the active layer of the emitter is re-centred by the presence of the resonant cavity. Said cavity allows other wavelengths to pass through outside of its reflectivity strip, in particular shorter wavelengths. The superimposition of two spectra constitutes the emission spectrum of the emitter: stray wavelengths then appear, the presence of which is detrimental to the precision of the device.

### DESCRIPTION OF THE INVENTION

According to the invention, in order to filter these hindering wavelengths, the etch stop layer already present in the stack is used as filtering layer. This layer therefore plays two roles: that of stop layer and that of filtering layer.

As a stop layer, it is chemically different to the substrate to be eliminated; moreover, it has a composition that enables the undesirable wavelengths to be cut off.

For this filtering layer, a material similar to that used in the active layer is preferably chosen, which facilitates the manufacturing process.

For instance, for a layer in CdHgTe, its composition is chosen so as to absorb the stray radiation.

The invention therefore concerns a light emitting device comprising, between an input mirror and an output mirror forming a cavity, the latter having a reflectivity strip, a stack itself comprising an etch stop layer and an active layer characterised in that the stop layer is adapted to filter at least the wavelengths lower than the lower limit of the reflectivity strip.

The active layer is for example in CdₓHg₁₋ₓTe, and the stop layer in Cd_{y}Hg_{1-y}Te, where x<y.

If the stop layer is in Cd_{y}Hg_{1-y}Te, the cavity may comprise two stop layers of composition Cd_{z}Hg_{1-z}Te, where y<z.

The active layer is preferably in a material adapted to emitting in the infrared domain.

A device according to the invention may further comprise two Bragg mirrors, the stop layer being situated in the neighbourhood of the Bragg mirrors.

The stop layer is for example of a thickness between 50 nm and 200 nm.

A device according to the invention is for example adapted to emit at least one wavelength absorbed by methane or an oxide of carbon or an oxide of nitrogen.

### BRIEF DESCRIPTION OF DRAWINGS

FIG. 1 represents a known device of the prior art,

FIG. 2 represents an emission spectrum of a barrier/well/barrier assembly and a transmission spectrum of a pair of Bragg mirrors forming a microcavity,

FIG. 3 represents the spectrum of a known device, resulting from the microcavity effect (filtering of the luminescence by the mirrors),

FIG. 4 represents a stack according to the invention, with combined filtering layer and stop layer,

FIG. 5 represents the spectra of different elements of a device according to the invention,

FIG. 6 represents the resulting spectrum for a device according to the invention.

### DETAILED DESCRIPTION OF SPECIFIC EMBODIMENTS

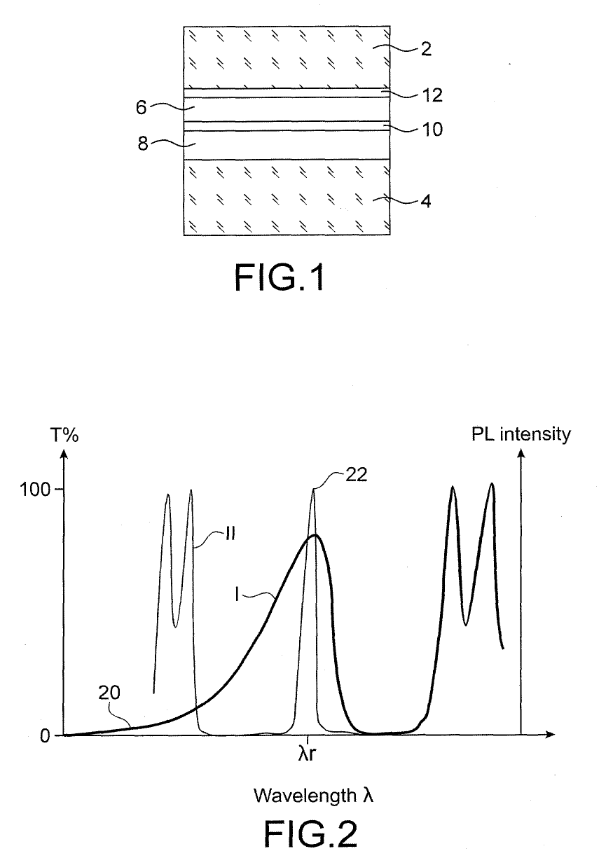

A first embodiment of the invention is illustrated in FIG. 4. The numerical references identical to those of FIG. 1 designate identical or similar elements.

In this structure of an emitting device according to the invention, the stop layer is also a filtering layer 20, for example a layer in CdHgTe, the composition of which is chosen so that this layer absorbs the stray radiation. In the case where the layer 10 is also in CdHgTe, this layer 20 has a Cd content higher than that of the well 10. The barrier layers 6, 8 may also have compositions of type CdHgTe, in which case the Cd content of the layer 20 is between that of the well 10 and that of the barriers 6, 8.

The layer 20 therefore does not hinder the emission at the wavelength of the device and does not participate, either, in the emission at this wavelength.

This layer 20 is inserted directly in the structure, it may therefore be formed by epitaxy at the same time as the cavity (barriers 6,8+well 10).

This layer 20 is situated directly in the neighbourhood of the Bragg mirrors 2 or 4, which may be deposited on this same layer.

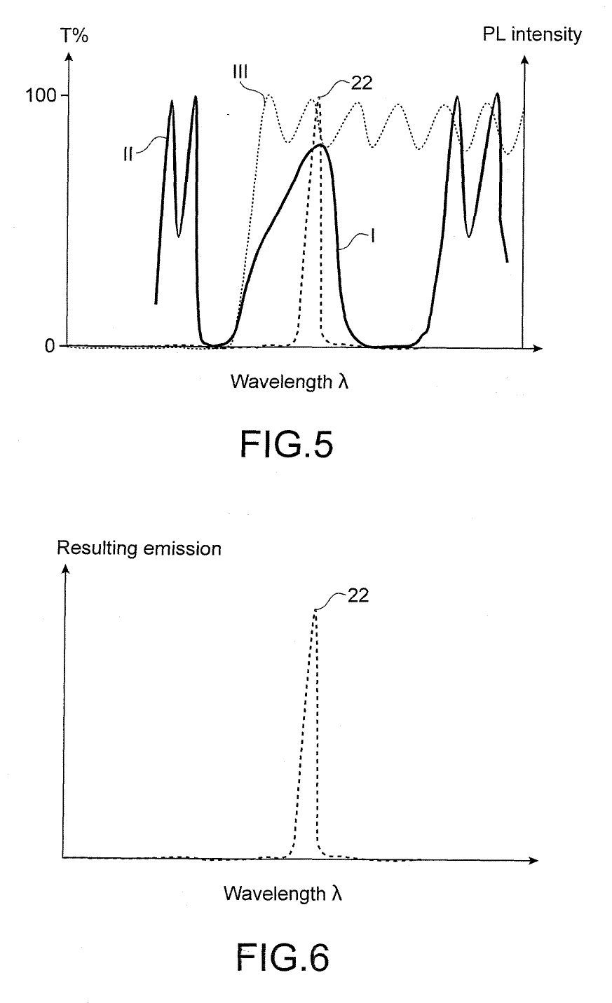

FIG. 5 is equivalent to FIG. 2 but the transmission spectrum III of a thick layer equivalent to the filter layer 20 has been added and in which the composition of CdHgTe alloy has been chosen to absorb the part of the photoluminescence spectrum situated below the lower cut-off of the mirrors, in other words to filter the wavelengths lower than the lower limit of the reflectivity strip of the cavity.

The photoluminescence spectrum (curve I), which has a tail 20 on the high energies side may be recognised; superimposed on this spectrum is also represented curve II, or reflectivity spectrum typical of a pair of Bragg mirrors (Fabry-Perrot resonator).

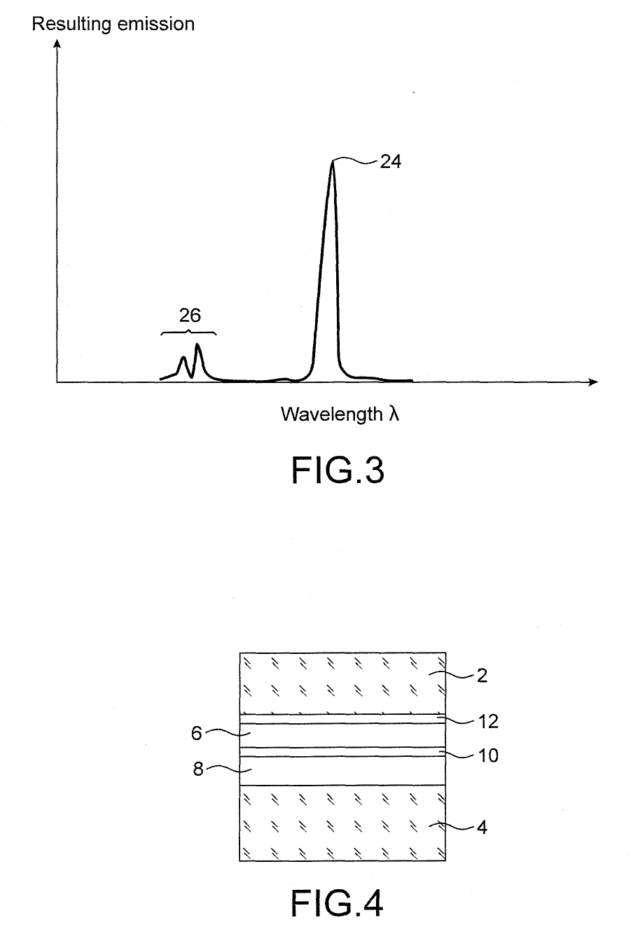

The resulting emission spectrum is, due to the fact of the filter layer, purged of the stray emission 26 visible in FIG. 3.

The filter layer 20 may not be a thick layer (it has for example a thickness of between 50 nm and 200 nm). It absorption efficiency may therefore be less than that shown in FIG. 5. However this disadvantage is compensated by the fact that the photons complete multiple back and forth movements in the cavity before being extracted via the output mirror. Finally, the emission spectrum of the emitter will be efficiently cleared of any stray emission on the high energies side. The spectral selectivity of this type of structure is thereby assured by the addition, in the structure, of the filter layer.

According to one embodiment of a device according to the invention, with stop layer accumulating the function of filter, the stack is developed according to a process comprising the following steps. On a substrate, is grown, for example by epitaxy:
a filter layer 20 that also possesses the function of stop layer,
a barrier layer 6,
an emitting layer 10,
a barrier layer 8.

A first mirror is then deposited. By etching down to the stop layer, the substrate is eliminated. On the freed surface is deposited the second mirror.

The filter/stop layer has a composition in cadmium greater than that of the emitting layer and less than that of the barrier layers. Its thickness may be low because it is situated in the cavity. It thereby benefits from backward and forward movements of photons in this cavity.

For example, for an emitter that is intended to detect CH₄ (at 3.31 μm) and for a microcavity known as “λ” (microcavity in which the thickness is exactly λ/n, where λ is the wavelength of the photons (here: 3.31 μm) and where n is the index of the material), the structure of a cavity according to the invention is as follows:
substrate,
mirror: 3 ZnS/YF₃ bi-layers of thickness for example 2700 nm,
filter/stop layer 20: composition in cadmium 0.40 (CdₓHg₁₋ₓTe, x=0.4), thickness 100 nm,
barrier layer 6: composition in cadmium 0.65 (Cd_{z}Hg_{1-z}Te, z=0.65), thickness 350 nm,
emitting layer 10: composition in cadmium 0.36 (Cd_{y}Hg_{1-y}Te, y=0.36), thickness 200 nm,
barrier layer 8: composition in cadmium 0.65 (Cd_{z}Hg_{1-z}Te, z=0.65), thickness 430 nm,
mirror: 6 ZnS/YF₃ bi-layers of thickness for example 5400 nm.

The composition x in cadmium of the filter/barrier layer may take all values between the composition y in Cd of the emitting layer and that (z) of the barriers. The thickness of this layer can typically vary between 50 nm and 200 nm. The thicknesses of the other layers, particularly those of the barrier layers, will then be recalculated to conserve a cavity “λ”.

Other gases may also be detected by adapting the composition of the material, for example oxides of carbon (CO, and/or CO₂) and/or oxides of nitrogen (NO).

Moreover, other materials may be used such as for example GaInAsSb compounds with all possible compositions such as the ternaries GaAsSb and InAsSb.

1-6. (canceled)

7. A light emitting device comprising:
between an input mirror and an output mirror forming a cavity, the output mirror including a reflectivity strip, a stack itself comprising an etch stop layer and an active layer,
the stop layer being adapted to filter at least wavelengths lower than a lower limit of the reflectivity strip,
the active layer being in CdₓHg₁₋ₓTe, and the stop layer in Cd_{y}Hg_{1-y}Te, where x<y.

8. A device according to claim 7, the active layer being in a material adapted to emit in the infrared domain.

9. A device according to claim 7, the stop layer being in Cd_{y}Hg_{1-y}Te, the cavity further comprising two barrier layers of composition Cd_{z}Hg_{1-z}Te, where y<z.

10. A device according to claim 7, the input and output mirrors being two Bragg mirrors, the stop layer being situated in the neighborhood of the Bragg mirrors.

11. A device according to claim 7, the stop layer having a thickness of between 50 nm and 200 nm.

12. A device according to claim 7, adapted to emit at least one wavelength absorbed by methane or an oxide of carbon or an oxide of nitrogen.

13. A light emitting device comprising:
between an input mirror and an output mirror forming a cavity, the output mirror including a reflectivity strip, a stack itself comprising an etch stop layer and an active layer,
the stop layer being adapted to filter at least wavelengths lower than a lower limit of the reflectivity strip,
the active layer being in CdₓHg₁₋ₓTe, and the stop layer in Cd_{y}Hg_{1-y}Te, where x<y,
the cavity further comprising two barrier layers of composition Cd_{z}Hg_{1-z}Te, where y<z.

14. A device according to claim 13, the active layer being in a material adapted to emit in the infrared domain.

15. A device according to claim 13, the input and output mirrors being two Bragg mirrors, the stop layer being situated in the neighborhood of the Bragg mirrors.

16. A device according to claim 13, the stop layer having a thickness of between 50 nm and 200 nm.

17. A device according to claim 13, adapted to emit at least one wavelength absorbed by methane or an oxide of carbon or an oxide of nitrogen.

18. A light emitting device comprising:
between an input mirror and an output mirror forming a cavity, the output mirror including a reflectivity strip, a stack itself comprising an etch stop layer and an active layer,
the stop layer being adapted to filter at least wavelengths lower than the lower limit of the reflectivity strip,
the active layer being in CdₓHg₁₋ₓTe, and the stop layer in Cd_{y}Hg_{1-y}Te, where x<y,
the cavity further comprising two barrier layers of composition Cd_{z}Hg_{1-z}Te, wherein y<z,
the input and output mirrors being two Bragg mirrors,
the stop layer being situated in the neighborhood of the Bragg mirrors and having a thickness of between 50 nm and 200 nm.

19. A device according to claim 18, the active layer being in a material adapted to emit in the infrared domain.

20. A device according to claim 18, adapted to emit at least one wavelength absorbed by methane or an oxide of carbon or an oxide of nitrogen.
